(19) United States
(12) Patent Application Publication
(10) Pub. No.: US 2016/0056123 A1
(43) Pub. Date: Feb. 25, 2016

(54) SEALING SHEET, METHOD FOR PRODUCING SEMICONDUCTOR DEVICE, AND SUBSTRATE WITH SEALING SHEET

(71) Applicant: NITTO DENKO CORPORATION, Osaka (JP)

(72) Inventors: Kosuke Morita, Ibaraki-shi (JP); Naohide Takamoto, Ibaraki-shi (JP)

(21) Appl. No.: 14/779,511

(22) PCT Filed: Mar. 19, 2014
(86) PCT No.: PCT/JP2014/057537

§ 371 Date: Sep. 23, 2015

(30) Foreign Application Priority Data
Mar. 26, 2013 (JP) 2013-064586

(51) Int. Cl. H01L 23/00; B32B 27/36; B32B 7/12

(52) U.S. Cl. CPC H01L 24/83; H01L 24/81; B32B 7/12; B32B 27/36; H01L 2224/8185; B32B 2405/00

(57) ABSTRACT

Provided are a sealing sheet capable of suppressing generation of voids due to satisfactory embeddability in irregularities of a semiconductor element or an adherend and with satisfactory workability before and after the sealing sheet is bonded to the adherend; a method for producing a semiconductor device using the sealing sheet; and a substrate with the sealing sheet bonded thereto. The sealing sheet includes a base material, and an under-fill material provided thereon having the following characteristics: a 90° peel strength from the base material of 1 mN/20 mm or more and 50 mN/20 mm or less; a rupture elongation of 10% or more at 25° C.; a minimum viscosity of 20,000 Pa·s or less at a temperature of 40° C. or more and 100° C. or less; and a minimum viscosity of 100 Pa·s or more at a temperature of 100° C. or more and 200° C. or less.

### TECHNICAL FIELD

The present invention relates to a sealing sheet, a method for producing a semiconductor device, and a substrate with a sealing sheet.

### BACKGROUND ART

In recent years, the demand for high density mounting associated with miniaturization and thinning of electronic instruments has been rapidly increased. In response to this demand, for semiconductor packages, the surface mounting type suitable for high density mounting has become mainstream in place of the conventional pin insertion type. Particularly, a flip chip mounting technique is developed in which a semiconductor chip and a substrate are electrically connected through a bump-shaped electrode (terminal) formed on the surface of the semiconductor chip.

In surface mounting, a space between a semiconductor element and a substrate is filled with a sealing resin in order to protect the surface of the semiconductor element and secure connection reliability between the semiconductor element and the substrate. As the sealing resin, liquid sealing resins are widely used, but in the case of liquid sealing resins, it is difficult to adjust the injection position and the injection amount, or the periphery of a bump having a reduced pitch cannot be sufficiently filled, and thus voids are generated. Accordingly, a technique has been proposed in which a space between a semiconductor element and a substrate is filled using a sheet-shaped sealing resin (under-fill sheet) (Patent Document 1).

The above-mentioned technique employs a procedure in which an adhesive layer (under-fill sheet) is disposed on the substrate, and the space between the semiconductor element and the substrate is filled with the adhesive layer disposed on the substrate at the time of connecting the semiconductor element to the substrate. In this filling process, a space between an adherent and a semiconductor element is easily filled.

### PRIOR ART DOCUMENT

### Patent Document

Patent Document 1: JP-A-2010-45104

### DISCLOSURE OF THE INVENTION

### Problems to be Solved by the Invention

However, in the technique described in Patent Document 1, an adhesive layer as an under-fill sheet is used in the form of a single layer, and the adhesive layer as a single layer is disposed directly on a substrate, so that it is difficult to handle the adhesive layer before disposition, and thus deposition at an unintended location and rupture of the adhesive layer may occur. On the other hand, a reinforcing material for reinforcing the under-fill sheet can be bonded to serve as a sealing sheet. In this case, the workability of the under-fill sheet before disposition on the substrate is improved owing to the presence of the reinforcing material, but since the reinforcing material is used in combination in addition to the under-fill sheet, the sealing sheet is required to have additional characteristics based on the combination of the reinforcing material at the time of disposition.

An object of the present invention is to provide a sealing sheet which is capable of suppressing generation of voids due to satisfactory embeddability in irregularities of a semiconductor element or an adherend and which has satisfactory workability before and after the sealing sheet is bonded to the adherend; a method for producing a semiconductor device using the sealing sheet; and a substrate with the sealing sheet bonded thereto.

### Means for Solving the Problems

The inventors of the present application have extensively conducted studies, and resultantly found that by employing the configuration described below, the above-mentioned object can be achieved, leading to completion of the present invention.

A sealing sheet according to the present invention includes a base material, and an under-fill material having the following characteristics provided on the base material:

a 90° peel strength from the base material is not less than 1 mN/20 mm and not more than 50 mN/20 mm;

a rupture elongation at 25° C. is 10% or more;

a minimum viscosity at a temperature of not lower than 40° C. and lower than 100° C. is 20,000 Pa·s or less; and a minimum viscosity at a temperature of not lower than 100° C. and not higher than 200° C. is 100 Pa·s or more.

It is necessary to peel off the base material from the under-fill material after the under-fill material is bonded to an adherend such as a substrate. In the sealing sheet, the base material can be smoothly peeled off without receiving an excessive load because the 90° peel strength of the under-fill material from the base material is not less than 1 mN/20 mm and not more than 50 mN/20 mm. Since the rupture elongation of the under-fill material at 25° C. is 10% or more, rupture does not occur even when expansion/contraction action is applied before bonding to the adherend, and in addition, rupture of the under-fill material itself can be prevented even when the peel strength is applied at the time of peeling off the under-fill material. Further, since the minimum viscosity of the under-fill material at a temperature of not lower than 40° C. and lower than 100° C. is 20,000 Pa·s or less, embeddability of the under-fill material in irregularities of the adherend is satisfactory, so that generation of voids between the under-fill material and the adherend can be prevented. Since the minimum viscosity of the under-fill material at a temperature of not lower than 100° C. and not higher than 200° C. is 100 Pa·s or more, generation of voids resulting from outgas components (moisture, organic solvent and so on) from the under-fill material can be suppressed. In this way, the characteristics of the sealing sheet are controlled so as to cope with the combination of the base material and the under-fill material, and therefore workability before and after the sealing sheet is bonded to the adherend can be improved while generation of voids is suppressed. In this specification, methods for measurement of the 90° peel strength, the rupture elongation, the minimum melt viscosity and the peel strength from the base material are as described in examples.

In the sealing sheet, it is preferred that the under-fill material contains a thermoplastic resin and a thermosetting resin. Particularly, it is preferred that the thermoplastic resin contains an acrylic resin, and the thermosetting resin contains an epoxy resin and a phenol resin. When the under-fill material contains these components, the above-mentioned characteristics required for the sealing sheet can be suitably exhibited.

Preferably, the thermosetting resin contains a thermosetting resin that is liquid at 25° C. (hereinafter, also referred to as a “liquid thermosetting resin”), and the ratio of the weight of the liquid thermosetting resin to the total weight of the thermosetting resin is not less than 5% by weight and not more than 40% by weight. Accordingly, the above-mentioned characteristics can be exhibited in good balance, and particularly, it becomes easy to adjust the viscosity, so that embeddability of the under-fill material in irregularities of the adherend can be improved.

Preferably, the under-fill material contains a flux agent. Accordingly, removal of an oxide film on the surface of an electrode such as a solder bump, improvement of wettability of solder, and so on can be achieved, and a bump electrode such as a solder bump provided on the semiconductor element can be efficiently melted to achieve more reliable electrical connection between the semiconductor element and the adherend.

In the sealing sheet, it is preferred that the base material contains a thermoplastic resin. Particularly, the thermoplastic resin is preferably polyethylene terephthalate for imparting mechanical characteristics such as moderate tension strength and elongation to the sealing sheet.

The present invention also includes a method for producing a semiconductor device which includes an adherend, a semiconductor element electrically connected to the adherend, and an under-fill material filling a space between the adherend and the semiconductor element, the method including the steps of:

providing the sealing sheet;
bonding the under-fill material of the sealing sheet to the adherend so as to cover a position of connection to the semiconductor element on the adherend;

peeling off the base material from the under-fill material bonded to the adherend; and

electrically connecting the semiconductor element and the adherend to each other through the bump electrode formed on the semiconductor element while filling the space between the adherend and the semiconductor element with the under-fill material.

In the production method, the under-fill material of the sealing sheet is bonded to the adherend, and the semiconductor element is then electrically connected thereto. Accordingly, at the time of peeling off the base material from the under-fill material, rupture, etc., of the under-fill material does not occur, and thus tackiness to the semiconductor element can be improved. In addition, since the under-fill material has a predetermined viscosity at the time of bonding, followability to irregularities of the adherend and the semiconductor element can be improved. Owing to these effects, a semiconductor device with high reliability, which is free from generation of voids, can be produced.

The present invention also includes a substrate with a sealing sheet, which includes a substrate, and the sealing seat bonded to the substrate.

### BRIEF DESCRIPTION OF THE DRAWINGS

FIG. 1 is a sectional schematic view showing a sealing sheet according to one embodiment of the present invention.

FIG. 2A is a sectional schematic view showing a process for production of a semiconductor device according to one embodiment of the present invention.

FIG. 2B is a sectional schematic view showing a process for production of a semiconductor device according to one embodiment of the present invention.

FIG. 2C is a sectional schematic view showing a process for production of a semiconductor device according to one embodiment of the present invention.

### MODE FOR CARRYING OUT THE INVENTION

A sealing sheet according to the present invention includes a base material, and an under-fill material having the following characteristics provided on the base material:

a 90° peel strength from the base material is not less than 1 mN/20 mm and not more than 50 mN/20 mm;

a rupture elongation at 25° C. is 10% or more;
a minimum viscosity at a temperature of not lower than 40° C. and lower than 100° C. is 20,000 Pa·s or less; and a minimum viscosity at a temperature of not lower than 100° C. and not higher than 200° C. is 100 Pa·s or more.

The present invention also includes a method for producing a semiconductor device which includes an adherend, a semiconductor element electrically connected to the adherend, and an under-fill material filling a space between the adherend and the semiconductor element, the method including the steps of:

providing the sealing sheet;

bonding the under-fill material of the sealing sheet to the adherend so as to cover a position of connection to the semiconductor element on the adherend;

peeling off the base material from the under-fill material bonded to the adherend; and

electrically connecting the semiconductor element and the adherend to each other through the bump electrode formed on the semiconductor element while filling the space between the adherend and the semiconductor element with the under-fill material.

Hereinafter, an aspect will be described in which the sealing sheet is used in the method for producing a semiconductor device as one embodiment of the present invention.

[Providing Step]

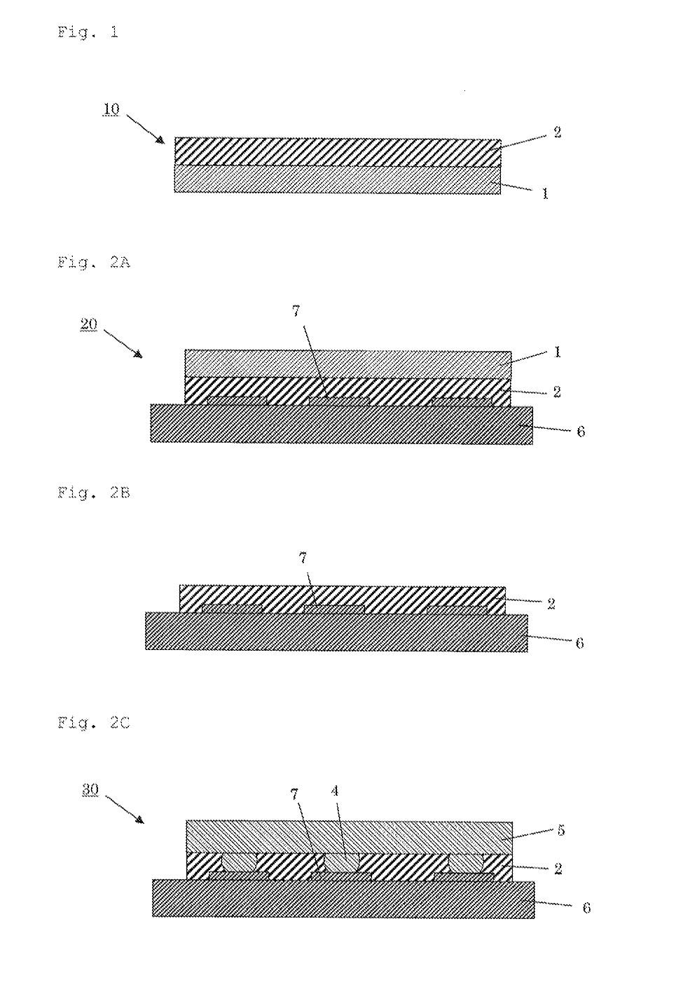

In the providing step, a sealing sheet 10 is provided (see FIG. 1). The sealing sheet 10 includes a base material 1, and an under-fill material 2 provided on the base material 1 and having the following characteristics:

the 90° peel strength from the base material is not less than 1 mN/20 mm and not more than 50 mN/20 mm;

the rupture elongation at 25° C. is 10% or more;

the minimum viscosity at a temperature of not lower than 40° C. and lower than 100° C. is 20,000 Pa·s or less; and

the minimum viscosity at a temperature of not lower than 100° C. and not higher than 200° C. is 100 Pa·s or more.

(Base Material)

The base material 1 is a reinforcement matrix for the sealing sheet 10. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base material 1 is preferably one having a permeability to ultraviolet rays.

In addition, examples of the material of the base material 1 include polymers such as crosslinked products of the resins described above. For the plastic film described above, an unstretched film may be used, or a film subjected to uniaxial or biaxial stretching may be used as necessary.

The surface of the base material 1 can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g. adhesive substance to be described) for improving adhesion with an adjacent layer, the retention property and so on.

For the base material 1, the same material or different materials can be appropriately selected and used, and one obtained by blending several materials can be used as necessary. The base material 1 can be provided thereon with a vapor-deposited layer of an electrically conductive substance made of a metal, an alloy, an oxide thereof, or the like and having a thickness of about 30 to 500 Å for imparting an antistatic property. The base material 1 may be a single layer or a multiple layer having two or more layers.

The thickness of the base material 1 can be appropriately determined in view of workability of the sealing sheet 10 and the like, but is generally about 5 to 200 μm, and is preferably 35 to 120 μm.

The base material 1 may contain various kinds of additives (e.g., colorant, filler, plasticizer, antiaging agent, antioxidant, surfactant, flame retardant, etc.) within the bounds of not impairing the effect of the present invention.

(Under-Fill Material)

The under-fill material 2 in this embodiment can be used as a sealing film that fills a space between a surface-mounted semiconductor element 5 and an adherend 6 (see FIG. 2C).

The 90° peel strength of the under-fill material 2 from the base material 1 is not less than 1 mN/20 mm and not more than 50 mN/20 mm. The lower limit of the 90° peel strength is not particularly limited as long as it is 1 mN/20 mm or more, but the 90° peel strength is preferably 5 mN/20 mm or more, more preferably 10 mN/20 mm or more. On the other hand, the upper limit of the 90° peel strength is not particularly limited as long as it is 50 mN/20 mm or less, but the 90° peel strength is preferably 40 mN/20 mm or less, more preferably 30 mN/20 mm or less. When a 90° peel strength in the above-described range is employed, the base material 1 can be smoothly peeled off without application of an excessive load on the sealing sheet 10 at the time of peeling off the base material 1 from the under-fill material 2 after the under-fill material 2 is bonded to the adherend 6 such as a substrate (see FIG. 2B), and occurrence of inadvertent peeling between the under-fill material and the base material during handling of the sealing sheet can be prevented.

The rupture strength of the under-fill material 2 at 25° C. is 10% or more, preferably 50% or more, more preferably 100% or more. The under-fill material 2 is not ruptured even when expansion/contraction action is applied before bonding to the adherend in handling of the sealing sheet 10, and in addition, rupture of the under-fill material 2 itself can be prevented even when the peel strength is applied at the time of peeling off the under-fill material 2. The upper limit of the rupture elongation is preferably as high as possible, but cannot exceed about 1000% from a physical point of view.

The viscosity of the under-fill material 2 at a temperature of not lower than 40° C. and lower than 100° C. is 20,000 Pa·s or less, preferably 15,000 Pa·s or less, more preferably 10,000 Pa·s or less. When the viscosity is in the above-mentioned range, embeddability of the under-fill material 2 in irregularities of the adherend 6 is satisfactory, so that generation of voids between the under-fill material 2 and the adherend 6 can be prevented. The lower limit of the viscosity is not particularly limited, but is preferably 1000 Pa·s or more from the viewpoint of shape retainability at the time of bonding of the substrate etc. to the adherend.

The minimum viscosity of the under-fill material 2 at a temperature of not lower than 100° C. and not higher than 200° C. is 100 Pa·s or more, preferably 500 Pa·s or more, more preferably 1000 Pa·s or more. When a minimum viscosity in the above-mentioned range is employed, generation of voids resulting from outgas (moisture, organic solvent and so on) from the under-fill material can be suppressed. The upper limit of the minimum viscosity is not particularly limited, but is preferably 10,000 Pa·s or less, more preferably 5,000 Pa·s or less from the viewpoint of embeddability in irregularities of the semiconductor element.

The material that forms the under-fill material is, for example, a combination of a thermoplastic resin and a thermosetting resin. Alternatively, a thermoplastic resin or a thermosetting resin alone can be used.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, and a fluororesin. These thermoplastic resins can be used alone, or in combination of two or more thereof. Among these thermoplastic resins, an acrylic resin, which has less ionic impurities, has a high heat resistance and can ensure the reliability of a semiconductor element, is especially preferable.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group and an eicosyl group.

Other monomers for forming the polymer are not particularly limited, and examples thereof include carboxyl group-containing monomers such as acrylic acid, methacrylic acid, carboxyethyl acrylate, carboxypentylacrylate, itaconic acid, maleic acid, fumaric acid and crotonic acid, acid anhydride monomers such as maleic anhydride and itaconic anhydride, hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate and (meth)acryloyloxynaphthalenesulfonic acid, and phosphoric acid group-containing monomers such as 2-hydroxyethylacryloyl phosphate, cyano group-containing monomers such as acrylonitrile.

Examples of the thermosetting resin include a phenol resin, an amino resin, an unsaturated polyester resin, an epoxy resin, a polyurethane resin, a silicone resin and a thermosetting polyimide resin. These resins can be used alone, or in combination of two or more thereof. Particularly, an epoxy resin containing less ionic impurities that corrode a semiconductor element is preferable. A curing agent for the epoxy resin is preferably a phenol resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type or a tetraphenylol ethane type, or an epoxy resin such as a hydantoin type, a trisglycidyl isocyanurate type or a glycidyl amine type is used. They can be used alone, or in combination of two or more thereof. Among these epoxy resins, a novolak type epoxy resin, a biphenyl type epoxy resin, a trishydroxyphenyl methane type resin or a tetraphenylol ethane type epoxy resin is especially preferable. This is because the aforementioned resins have a high reactivity with a phenol resin as a curing agent, and are excellent in heat resistance and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in combination of two or more thereof. Among these phenol resins, a phenol novolak resin and a phenol aralkyl resin are especially preferable. This is because the connection reliability of a semiconductor device can be improved.

For example, the epoxy resin and the phenol resin are preferably blended at such a blending ratio that the equivalent of the hydroxyl group in the phenol resin per one equivalent of the epoxy group in the epoxy resin component is 0.5 to 2.0 equivalents. More preferable is 0.8 to 1.2 equivalents. That is, if the blending ratio of the resins falls outside of the aforementioned range, the curing reaction does not proceed sufficiently, so that properties of the epoxy resin cured products are easily deteriorated.

In the present embodiment, an under-fill material using an epoxy resin, a phenol resin and an acrylic resin is especially preferable. These resins have less ionic impurities and has a high heat resistance, and therefore can ensure the reliability of a semiconductor element. The blending ratio in this case is such that the mixed amount of the epoxy resin and the phenol resin is 10 to 200 parts by weight based on 100 parts by weight of the acrylic resin component.

Preferably, the thermosetting resin contains a liquid thermosetting resin. In this case, the ratio of the weight of the liquid thermosetting resin to the total weight of the thermosetting resin is preferably not less than 5% by weight and not more than 40% by weight, more preferably not less than 10% by weight and not more than 35% by weight. Accordingly, the above-mentioned necessary characteristics of the under-fill material 2 can be exhibited in good balance, and particularly, embeddability of the under-fill material 2 in irregularities of the adherend 6 can be improved. As the liquid thermosetting resin, one having a weight average molecular weight of 1000 or less can be suitable used among the thermosetting resins described above. The weight average molecular weight can be measured using the following method. A sample is dissolved in THF in a concentration of 0.1 wt %, and a weight average molecular weight is measured in terms of polystyrene using GPC (gel permeation chromatography). Detailed measurement conditions are as follows.

<Conditions for Measurement of Weight Average Molecular Weight>

GPC device: HLC-8120 GPC manufactured by TOSOH CORPORATION Column: (GMHHR-H)+(GMHHR-H)+(G2000HHR) manufactured by TOSOH CORPORATION

Flow rate: 0.8 mL/min

Concentration: 0.1 wt %

Injection amount: 100 μL

Column temperature: 40° C.

Eluent: THF

A heat curing accelerating catalyst for the epoxy resin and the phenol resin is not particularly limited, and can be appropriately selected from known heat curing accelerating catalysts and used. The heat curing accelerating catalyst can be used alone, or in a combination of two or more kinds. As the heat curing accelerating catalyst, for example, an amine-based curing accelerator, a phosphorus-based curing accelerator, an imidazole-based curing accelerator, a boron-based curing accelerator or a phosphorus-boron-based curing accelerator can be used.

A flux may be added to the under-fill material 2 for removing an oxide film on the surface of a solder bump to facilitate mounting of the semiconductor element. The flux is not particularly limited, and a previously known compound having a flux action may be used, but a carboxyl group-containing compound having a pKa of 3.5 or more (hereinafter, referred to as a “carboxyl group-containing compound”) is preferred. Accordingly, generation of carboxylic acid ions can be suppressed, so that reactivity with a thermosetting resin etc. having a reactive functional group such as an epoxy group can be suppressed. As a result, the carboxyl group-containing compound is not caused to immediately react with the thermosetting resin by heat generated during mounting of a semiconductor, and can sufficiently exhibit a flux function with heat subsequently supplied over time.

(Carboxyl Group-Containing Compound Having a pKa of 3.5 or More)

The carboxyl group-containing compound according to this embodiment is not particularly limited as long as it is a compound containing at least one carboxyl group in each molecule, having an acid dissociation constant pKa of 3.5 or more, and having a flux function. The pKa of the carboxyl group-containing compound should be 3.5 or more, but is preferably 3.5 or more and 7.0 or less, more preferably 4.0 or more and 6.0 or less, from the viewpoint of suppression of a reaction with an epoxy resin as well as over time-stability of flexibility and performance of a flux function. When two or more carboxyl groups are present, a first dissociation constant pKa₁ is defined as an acid dissociation constant, and the first dissociation constant pKa₁ preferably falls within the above-mentioned range. The pKa can be determined by measuring an acid dissociation constant Ka=[H₃O⁺] [B⁻]/[BH] under the condition of a dilute aqueous solution of the carboxyl group-containing compound and using the equation of pKa=−log Ka. Here, BH represents a carboxyl group-containing compound, and B⁻ represents a conjugate base of the carboxyl group-containing compound. The pKa can be measured in such a manner that a hydrogen ion concentration is measured using a pH meter, and the pKa is calculated from the concentration of a relevant substance and the hydrogen ion concentration.

The carboxyl group-containing compound is preferably at least one selected from the group consisting of an aromatic carboxylic acid having in each molecule at least one substituent selected from the group consisting of an alkyl group, an alkoxy group, an aryloxy group, an aryl group and an alkylamino group (hereinafter, referred to merely as “aromatic carboxylic acid” in some cases), and an aliphatic carboxylic acid having in each molecule one or more carboxyl group and having a carbon number of 8 or more (hereinafter, referred to merely as “aliphatic carboxylic acid” in some cases).

(Aromatic Carboxylic Acid)

The aromatic carboxylic acid is not particularly limited as long as it has in each molecule at least one substituent selected from the group consisting of an alkyl group, an alkoxy group, an aryloxy group, an aryl group and an alkylamino group. The backbone of the aromatic carboxylic acid, excluding the above-mentioned substituent, is not particularly limited, and examples thereof include benzoic acid and naphthalenecarboxylic acid. The aromatic carboxylic acid has the above-mentioned substituent on the aromatic ring of these backbones. Above all, benzoic acid is preferable as the backbone of the aromatic carboxylic acid from the viewpoint of stability in the sheet-like sealing composition and low reactivity with an epoxy resin.

The aromatic carboxylic acid is preferably a benzoic acid derivative in which at least one of hydrogen atoms specifically at 2-, 4- and 6-positions are independently substituted with an alkyl group, an alkoxy group, an aryloxy group, an aryl group or an alkylamino group (hereinafter, referred to merely as “benzoic acid derivative” in some cases). In the above-mentioned benzoic acid derivative, predetermined substituents are present alone or in combination at least one of 2-, 4- and 6-positions in benzoic acid. Examples of the specific substitution position in the benzoic acid derivative include 2-position, 4-position, 2- and 4-positions, 2- and 6-positions, and 2-, 4- and 6-positions. Above all, it is preferable to have a substituent at 2- or 4 position for suppressing a reaction with an epoxy resin, retaining the over time-stability of flexibility, and allowing a flux function to be especially efficiently performed.

Examples of the alkyl group in the aromatic carboxylic acid may include alkyl groups having a carbon number of 1 to 10, such as a methyl group, an ethyl group, an n-propyl group, an i-propyl group, an n-butyl group, an i-butyl group, a sec-butyl group, a t-butyl group, an n-pentyl group, an n-hexyl group, an n-heptyl group and an n-octyl group. Among them, a methyl group or an ethyl group is preferable from the viewpoint of adjustment of a pKa and performance of a flux function.

Examples of the alkoxy group include alkoxy groups having a carbon number of 1 to 10, such as a methoxy group, an ethoxy group, an n-propoxy group, an n-butoxy group, an n-hexanoxy group, an i-propoxy group, an n-butoxy group, a 2-methylpropoxy group and a t-butoxy group, but among them, an alkoxy group having a carbon number of 1 to 4 is preferable, a methoxy group and an ethoxy group are further preferable, and a methoxy group is especially preferable, from the same viewpoint as described above.

Examples of the aryloxy group include a phenoxy group and a p-triloxy group, and a phenoxy group is preferable from the same viewpoint as described above.

Examples of the aryl group include aryl groups having a carbon number of 6 to 20, such as a phenyl group, a toluyl group, a benzyl group, a methylbenzyl group, a xylyl group, a mesityl group, a naphthyl group and an anthryl group, and a phenyl group is preferable from the same viewpoint as described above.

As the alkylamino group, an amino group having as a substituent an alkyl group having a carbon number of 1 to 10 can be suitably used. Specific examples of the alkylamino group include a methylamino group, an ethylamino group, a propylamino group, a dimethylamino group, a diethylamino group and a dipropylamino group, and a dimethylamino group is preferable from the same viewpoint as described above.

In the alkyl group, alkoxy group, aryloxy group, aryl group or alkylamino group described above, one or more hydrogen atoms may be each independently substituted. Examples of such additional substituent include alkoxy groups having a carbon number of 1 to 4, such as a methoxy group, an ethoxy group, an n-propoxy group, an i-propoxy group, an n-butoxy group, a 2-methylpropoxy group, a 1-methylpropoxy group and a t-butoxy group, a cyano group, cyanoalkyl groups having a carbon number of 2 to 5 such as a cyanomethyl group, a 2-cyanoethyl group, a 3-cyanopropyl group and a 4-cyanobutyl group, alkoxycarbonyl groups having a carbon number of 2 to 5, such as a methoxycarbonyl group, an ethoxycarbonyl group and a t-butoxycarbonyl group, alkoxycarbonylalkoxy groups having a carbon number of 3 to 6, such as a methoxycarbonylmethoxy group, an ethoxycarbonylmethoxy group and a t-butoxycarbonylmethoxy group, halogen atoms such as fluorine and chlorine, and fluoroalkyl groups such as a fluoromethyl group, a trifluoromethy group and a pentafluoroethyl group.

As a benzoic acid derivative having a specific combination of substitution position and a substituent, 2-aryloxybenzoic acid, 2-arylbenzoic acid, 4-alkoxybenzoic acid and 4-alkylaminobenzoic acid are preferable.

The benzoic acid derivative preferably contains no hydroxyl group. By eliminating a hydroxyl group which can be a point of reaction with an epoxy group, the sealing composition can retain a flexibility over time, and suitably exhibit a flux function.

(Aliphatic Carboxylic Acid)

The aliphatic carboxylic acid is not particularly limited, and may be any of a chain aliphatic (mono)carboxylic acid, a cycloaliphatic (mono)carboxylic acid, a chain aliphatic polyvalent carboxylic acid and a cycloaliphatic polyvalent carboxylic acid. Those forms may be combined and used.

Examples of the chain aliphatic (mono) carboxylic acid include saturated aliphatic acids such as octanoic acid, nonanoic acid, decanoic acid, dodecanoic acid, tetradecanoic acid, hexadecanoic acid, heptadecanoic acid and octadecanoic acid, and unsaturated aliphatic acids such as oleic acid, elaidic acid, erucic acid, nervonic acid, linolenic acid, stearidonic acid, eicosapentaenoic acid, linoleic acid and linolenic acid.

Examples of the cycloaliphatic (mono) carboxylic acid include monocyclic carboxylic acids such as cycloheptanecarboxylic acid and cyclooctanecarboxylic acid, and polycyclic or bridged cycloaliphatic carboxylic acids having a carbon number of 8 to 20, such as norbornanecarboxylic acid, tricyclodecanecarboxylic acid, tetracyclododecanecarboxylic acid, adamantanecarboxylic acid, methyladamantanecarboxylic acid, ethyladamantanecarboxylic acid and butyladamantanecarboxylic acid.

Examples of the chain aliphatic polyvalent carboxylic acid include carboxylic acids with one or more carboxyl group further added to the chain aliphatic (mono)carboxylic acid, and among them, chain aliphatic dicarboxylic acids are preferable in that reactivity with an epoxy resin is low and a flux function is suitably exhibited. Examples of the chain aliphatic dicarboxylic acid include octanedioic acid, nonanedioic acid, decanedioic acid, dodecanedioic acid, tetradecanedioic acid, hexadecanedioic acid, heptadecanedioic acid and octadecanedioic acid, and among them, a chain aliphatic dicarboxylic acid having a carbon number of 8 to 12 is preferable.

Examples of the cycloaliphatic polyvalent carboxylic acid include carboxylic acids with one or more carboxyl group further added to the cycloaliphatic (mono) carboxylic acid, and among them, cycloaliphatic dicarboxylic acids are preferable from the viewpoint of low reactivity to an epoxy resin and performance of a flux function. Examples of the cycloaliphatic dicarboxylic acid include monocyclic dicarboxylic acids such as cyclohexanedicarboxylic acid, cycloheptanedicarboxylic acid and cyclooctanedicarboxylic acid, and polycyclic or bridged cycloaliphatic dicarboxylic acids such as norbornanedicarboxylic acid and adamantanedicarboxylic acid.

In the aliphatic carboxylic acid having a carbon number of 8 or more, one or more hydrogen atoms may be substituted with the additional substituent.

The added amount of a carboxyl group-containing compound as a flux agent may be such an amount that the flux function is exhibited, and is preferably 0.1 to 20% by weight, more preferably 0.5 to 10% by weight based on the total weight of organic components in the under-fill material 2.

In this embodiment, the under-fill material 2 may be colored as necessary. In the under-fill material 2, the color shown by coloring is not particularly limited, but is preferably, for example, black, blue, red and green. For coloring, a colorant can be appropriately selected from known colorants such as pigments and dyes and used.

An inorganic filler can be appropriately blended with the under-fill material 2. Blending of the inorganic filler allows impartment of electrical conductivity, improvement of thermal conductivity, adjustment of a storage elastic modulus, and so on.

Examples of the inorganic filler include various inorganic powders made of ceramics such as silica, clay, plaster, calcium carbonate, barium sulfate, aluminum oxide, beryllium oxide, silicon carbide and silicon nitride, metals such as aluminum, copper, silver, gold, nickel, chromium, lead, tin, zinc, palladium and solder, or alloys, and carbon. They can be used alone, or in combination of two or more thereof. Above all, silica, particularly fused silica is suitably used.

The average particle diameter of the inorganic filler is not particularly limited, but is preferably in a range of 0.005 to 10 μm, more preferably in a range of 0.01 to 5 μm, further preferably in a range of 0.05 to 2.0 μm. If the average particle diameter of the inorganic filler is less than 0.005 μm, the flexibility of the under-fill material may be thereby depressed. On the other hand, if the average particle diameter is more than 10 μm, the particle diameter may be so large with respect to a gap sealed by the under-fill material that the sealing property is depressed. In the present invention, inorganic fillers having mutually different average particle diameters may be combined and used. The average particle diameter is a value determined by a photometric particle size analyzer (manufactured by HORIBA, Ltd.; Unit Name: LA-910).

The blending amount of the inorganic filler is preferably 10 to 400 parts by weight, more preferably 50 to 250 parts by weight, based on 100 parts by weight of the organic resin component of the under-fill material. If the blending amount of the inorganic filler is less than 10 parts by weight, the storage elastic modulus may be reduced, thereby considerably deteriorating the stress reliability of a package. On the other hand, if the blending amount of the inorganic filler is more than 400 parts by weight, the fluidity of the under-fill material 2 may be depressed, so that the under-fill material may not sufficiently fill up raised and recessed portions of the substrate or semiconductor element, thus leading to generation of voids and cracks.

Besides the inorganic filler, other additives can be blended with the under-fill material 2 as necessary. Examples of other additives include a flame retardant, a silane coupling agent and an ion trapping agent. Examples of the flame retardant include antimony trioxide, antimony pentaoxide and a brominated epoxy resin. They can be used alone, or in combination of two or more thereof. Examples of the silane coupling agent include β-(3,4-epoxycyclohexyl)ethyltrimethoxysilane, γ-glycidoxypropyltrimethoxysilane and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

Further, the water absorption rate of the under-fill material 2 at a temperature of 23° C. and a humidity of 70% before heat curing is preferably 1% by weight or less, more preferably 0.5% by weight or less. The under-fill material 2 has such a water absorption rate as described above, whereby absorption of moisture into the under-fill material 2 can be suppressed, so that generation of voids during mounting of the semiconductor element 5 can be more efficiently suppressed. The lower limit of the water absorption rate is preferably as low as possible, and is preferably substantially 0% by weight, more preferably 0% by weight.

The thickness of the under-fill material 2 (total thickness in the case of a multiple layer) is not particularly limited, but may be about 10 μm to 100 μm when considering the strength of the under-fill material 2 and performance of filling a space between the semiconductor element 5 and the adherend 6. The thickness of the under-fill material 2 may be appropriately set in consideration of the gap between the semiconductor element 5 and the adherend 6 and the height of the bump electrode.

The under-fill material 2 of the sealing sheet 10 is preferably protected by a separator (not shown). The separator has a function as a protective material for protecting the under-fill material 2 until actual use. The separator is peeled off when the adherend 6 is attached onto the under-fill material 2 of the sealing sheet. As the separator, polyethylene terephthalate (PET), polyethylene, polypropylene, or a plastic film or paper of which a surface is coated with a release agent such as a fluorine-based release agent or a long-chain alkyl acrylate-based release agent can be used.

(Method for Producing a Sealing Sheet)

First, the base material 1 can be film formed by a previously known film formation method. Examples of the method for a film formation may include a calender film formation method, a casting method in an organic solvent, an inflation extrusion method in a closed system, a T-die extrusion method, a co-extrusion method and a dry lamination method.

For example, the under-fill material 2 is prepared in the following manner. First, an adhesive composition which is a material for forming the under-fill material 2 is prepared. A thermoplastic component, a thermosetting resin, various kinds of additives and so on are blended in the adhesive composition as described in the section relating to the under-fill material.

Next, the prepared adhesive composition is applied onto a base material separator in a predetermined thickness to form a coating film, followed by drying the coating film under predetermined conditions to form an under-fill material. The coating method is not particularly limited, and examples thereof include roll coating, screen coating and gravure coating. For drying conditions, for example, the drying temperature is in a range of 70 to 160° C., and the drying time is in a range of 1 to 5 minutes. The under-fill material may be formed by applying a pressure-sensitive adhesive composition onto a separator to form a coating film, followed by drying the coating film under the aforementioned conditions. Thereafter, the under-fill material is bonded onto the base material separator together with the separator.

Subsequently, the separator is peeled off from the under-fill material 2, and the under-fill material and the base material are bonded to each other. Bonding can be performed by, for example, compression bonding. At this time, the lamination temperature is not particularly limited, and for example, it is preferably 30 to 100° C., more preferably 40 to 80° C. The linear pressure is not particularly limited, and for example, it is preferably 0.98 to 196 N/cm, more preferably 9.8 to 98 N/cm. Next, the base material separator on the under-fill material is peeled off to obtain a sealing sheet according to this embodiment.

[Bonding Step]

In the bonding step, the under-fill material 2 of the sealing sheet is bonded to the adherend 6 so as to cover the position of connection to the semiconductor element on the adherend 6 (see FIG. 2A). First, a separator arbitrarily provided on the under-fill material 2 of the sealing sheet 10 is appropriately peeled off, and the under-fill material 2 and the adherend 6 are bonded to each other by compression bonding with the circuit surface of the adherend 6, which is provided with the conducting material 7, and the under-fill material 2 facing each other.

As the adherend 6, a lead frame, various kinds of substrates such as and a circuit substrate (such as a wiring circuit substrate), and other semiconductor elements can be used. Examples of the material of the substrate include, but are not limited to, a ceramic substrate and a plastic substrate. Examples of the plastic substrate include an epoxy substrate, a bismaleimide triazine substrate, a polyimide substrate and a glass epoxy substrate.

In this embodiment, it is preferred to bond the adherend and the under-fill material to each other by heat pressure-bonding. Heat pressure-bonding can be performed by known pressing means such as a compression roll. As the pressing condition, the pressure should be 0.2 MPa or more, and is preferably not less than 0.2 MPa and not more than 1 MPa, more preferably not less than 0.4 Pa and not more than 0.8 Pa. As the heat pressure-bonding temperature condition, the temperature should be 40° C. or higher, and is preferably not lower than 40° C. and not higher than 120° C., more preferably not lower than 60° C. and not higher than 100° C. Heat pressure-bonding may be performed under a reduced pressure. As the reduced pressure condition, the pressure should be 10,000 Pa or less, and is preferably 5,000 Pa or less, more preferably 1000 Pa or less. The lower limit of the reduced pressure condition is not particularly limited, but is preferably 10 Pa or more from the viewpoint of productivity. When bonding is performed under predetermined heat pressure-bonding conditions, the under-fill material can sufficiently follow irregularities of the surface of the adherend, so that bubbles at the interface between the adherend and the under-fill material can be considerably reduced to improve tackiness. Accordingly, generation of voids at the interface can be suppressed, and as a result, a semiconductor device excellent in connection reliability between a semiconductor element and an adherend can be efficiently produced.

At the time of completion of the bonding step, a substrate 20 with a sealing sheet in which the sealing sheet 10 is bonded to the adherend 6 is obtained. In the substrate 20 with a sealing sheet, the base material 1 serves as a protective material for the under-fill material 2, and therefore the substrate 20 with a sealing sheet can be left on standby as an intermediate product for production of a semiconductor device for, for example, adjustment of production.

[Peeling Step]

In the peeling step, the base material 1 is peeled off from the under-fill material 2 bonded to the adherend 6 (see FIG. 2B). The base material 1 may be peeled off by human hands, or may be peeled off mechanically. As described above, the 90° peel strength of the under-fill material 2 from the base material is in a predetermined range, and therefore the base material 1 can be smoothly peeled off without causing rupture and deformation of the under-fill material 2, and peeling off the under-fill material 2 from the adherend 6.

[Connection Step]

In the connection step, the semiconductor element 5 and the adherend 6 are electrically connected to each other through the bump electrode 4 formed on the semiconductor element 5 while the space between the adherend 6 and the semiconductor element 5 is filled with the under-fill material 2 (see FIG. 2C).

(Semiconductor Element)

As the semiconductor element 5, a plurality of bump electrodes 4 may be formed on one circuit surface (see FIG. 2C), or bump electrodes may be formed on both circuit surfaces of the semiconductor element 5 (not illustrated). The material of the bump electrode such as a bump or an electrically conductive material is not particularly limited, and examples thereof include solders (alloys) such as a tin-lead-based metal material, a tin-silver-based metal material, a tin-silver-copper-based metal material, a tin-zinc-based metal material, a tin-zinc-bismuth-based metal material, a gold-based metal material and a copper-based metal material. The height of the bump electrode is also determined according to an application, and is generally about 15 to 100 μm. Of course, the heights of individual bump electrodes in the semiconductor element 5 may be the same or different.

When bump electrodes are formed on both surfaces of the semiconductor element, bump electrodes may be or may be not electrically connected to each other. Examples of electrical connection between bump electrodes include connection through a via called a TSV (Through Silicon Via) type.

The semiconductor element 5 can be prepared by a known method, and typically, a semiconductor wafer provided with a predetermined circuit and bump electrode is diced into individual pieces, and these pieces are picked up, so that individual semiconductor elements can be obtained.

In the method for producing a semiconductor device according to this embodiment, as the thickness of the under-fill material, the height X (μm) of the bump electrode formed on the surface of the semiconductor element and the thickness Y (μm) of the under-fill material preferably satisfies the following relationship:

0.5≦Y/X≦2 i.

The height X (μm) of the bump electrode and the thickness Y (μm) of the under-fill material satisfy the above relationship, whereby a space between the semiconductor element and the adherend can be sufficiently filled, and excessive protrusion of the under-fill material from the space can be prevented, so that contamination of the semiconductor element by the under-fill material, and so on can be prevented. When the heights of the respective bump electrodes are different, the height of the highest bump electrode is used as the reference.

(Electrical Connection)

As a procedure for electrically connecting the semiconductor element 5 and the adherend 6 to each other, the semiconductor element 5 is fixed to the adherend 6 in accordance with a usual method with the circuit surface of the semiconductor element 5 facing the adherend 6. For example, the bump (bump electrode) 4 formed on the semiconductor chip 5 is contacted with an electrically conductive material 7 (solder or the like) for bonding, which is attached to the connection pad of the adherend 6, and the electrically conductive material is melted while pressing, whereby electrical connection between the semiconductor chip 5 and the adherend 6 can be provided to fix the semiconductor chip 5 to the adherend 6. Since the under-fill material 2 is bonded to the circuit surface of the adherend 6, a space between the semiconductor chip 5 and the adherend 6 is filled with the under-fill material 2 concurrently with electrically connecting of the semiconductor chip 5 and the adherend 6.

Generally, in the connection step, the temperature is 100 to 300° C. as a heating condition, and the pressure is 0.5 to 500 N as a pressing condition. A heating and pressing treatment in the connection step may be carried out in a multiple stage. For example, such a procedure can be employed that a treatment is carried out at 150° C. and 100 N for 10 seconds, followed by carrying out a treatment at 300° C. and 100 to 200 N for 10 seconds. By carrying out the heating and pressing treatment in a multiple stage, a resin between the bump electrode and the pad can be efficiently removed to obtain a better metal-metal joint.

In the connection step, one or both of the bump electrode and the electrically conductive material are melted to connect the bump 4 of the circuit surface of the semiconductor element 5 and the electrically conductive material 7 on the surface of the adherend 6, and the temperature at which the bump 4 and the electrically conductive material 7 are melted is normally about 260° C. (for example 250° C. to 300° C.). The sealing sheet according to this embodiment can be made to have a such a heat resistance that it can endure a high temperature in the connection step, by forming the under-fill material 2 from an epoxy resin or the like.

Through the above procedure, a semiconductor device 30 with the semiconductor element 5 mounted on the adherend 6 can be produced. Since an under-fill material having the above-mentioned predetermined characteristics is used for production of the semiconductor device 30, generation of voids between the adherend and the under-fill material and between the under-fill material and the semiconductor element can be prevented, so that a semiconductor device with high reliability can be obtained.

[Under-Fill Material Curing Step]

When the under-fill material 2 is uncured after the heating treatment in the connection step, the under-fill material 2 is cured by heating. Accordingly, the circuit surface of the semiconductor element 5 can be protected, and connection reliability between the semiconductor element 5 and the adherend 6 can be secured. The heating conditions are not particularly limited, and heating may be performed at about 150 to 200° C. for 10 to 120 minutes. When the under-fill material is cured by heat applied in the connection step, the under-fill material curing step may be omitted.

[Sealing Step]

Next, a sealing step may be carried out for protecting the whole of a semiconductor device 30 including the mounted semiconductor element 5. The sealing step is carried out using a sealing resin. The sealing conditions at this time are not particularly limited, and normally the sealing resin is heat-cured by heating at 175° C. for 60 seconds to 90 seconds, but the present invention is not limited thereto and, for example, the sealing resin may be cured at 165° C. to 185° C. for several minutes.

The sealing resin is not particularly limited as long as it is a resin having an insulating property (insulating resin), and can be selected from sealing materials such as known sealing resins and used, but an insulating resin having elasticity is more preferable. Examples of the sealing resin include a resin composition containing an epoxy resin. Examples of the epoxy resin include the epoxy resins described previously as an example. The sealing resin by the resin composition containing an epoxy resin may contain, as a resin component, a thermosetting resin (phenol resin, etc.), a thermoplastic resin and so on in addition to an epoxy resin. The phenol resin can also be used as a curing agent for the epoxy resin, and examples of such a phenol resin include the phenol resins described previously as an example.

[Semiconductor Device]

A semiconductor device obtained using the sealing sheet will now be described with reference to the drawings (see FIG. 2E). In the semiconductor device 30 according to this embodiment, the semiconductor element 5 and the adherend 6 are electrically connected through the bump (bump electrode) 4 formed on the semiconductor element 5 and the electrically conductive material 7 provided on the adherend 6. The under-fill material 2 is placed between the semiconductor element 5 and the adherend 6 so as to fill a space therebetween. The semiconductor device 30 is obtained by the above-mentioned production method using the sealing sheet 10, and therefore, voids generated between the semiconductor element 5 and the under-fill material 2 are suppressed. Thus, surface protection of the semiconductor element 5, filling of a space between the semiconductor element 5 and the adherend 6 are kept at an adequate level, so that high reliability can be exhibited as the semiconductor device 30.

### EXAMPLES

Preferred Examples of the present invention will be illustratively described in detail below. However, for the materials, the blending amounts, and so on described in Examples, the scope of the present invention is not intended to be limited thereto unless definitely specified. The part(s) means “part(s) by weight”.

### Examples 1 to 4 and comparative examples 1 and 2

### Preparation of Sealing Sheet

The following components were dissolved in methyl ethyl ketone at a ratio shown in Table 1 to prepare an adhesive composition solution having a solid concentration of 23.6 to 60.6% by weight.

Epoxy resin 1 (liquid at 25° C.): trade name “Epicoat 828” manufactured by JER Corporation

Epoxy resin 2: trade name “Epicoat 1004” manufactured by JER Corporation

Phenol resin 1: trade name “Mirex XLC-4L” manufactured by Mitsui Chemicals, Incorporated

Phenol resin 2 (liquid at 25° C.): trade name “MEH-8005” manufactured by MEIWA PLASTIC INDUSTRIES, LTD.

Elastomer 1: acrylic acid ester-based polymer having an ethyl acrylate-methyl methacrylate as a main component (trade name “Paraclone W-197CM” manufactured by Negami Chemical Industrial Co., Ltd.)

Elastomer 2: acrylic acid ester-based polymer having a butyl acrylate-acrylonitrile as a main component (trade name “SG-P3” manufactured by Nagase chemteX Corporation)

Filler: spherical silica (trade name “SO-25R” manufactured by Admatechs)

Organic acid: o-anisic acid (trade name “Orthoanisic Acid” manufactured by Tokyo Chemical Industry Co., Ltd.)

Curing agent: Imidazole catalyst (trade name “2PHZ-PW” manufactured by Shikoku Chemicals Corporation)

Each adhesive composition solution was applied onto DIAFOIL MRA50 (manufactured by Mitsubishi Plastics, Inc.) as a base material, and dried at 130° C. for 2 minutes to form 30 μm-thick under-fill materials A to G, thereby preparing sealing sheets of the examples and comparative examples.

[Evaluation]

The following evaluations were performed using the sealing sheets of the examples and comparative examples (before heat curing of the under-fill material). The results are shown in Table 1.

(Measurement of 90° Peel Strength)

The peel strength (mN/20 mm) at the time of peeling off the under-fill material from the base material was measured. Specifically, the sealing sheet was cut to a size of 100 mm (length)×20 mm (width), and provided as a test piece. The test piece was set in a tension tester (trade name: “AUTOGRAPH AGS-H” manufactured by Shimadzu Corporation), a T-type tension test (JIS K6854-3) was conducted under the conditions of a temperature of 25±2° C., a peeling angle of 90°, a peel rate of 300 mm/min and a chuck-to-chuck distance of 100 mm.

(Measurement of Rupture Elongation)

Using a roll laminator (device name “MRK-600” manufactured by MCK CO., LTD.), an under-fill material was laminated at 70° C. and 0.2 MPa to obtain a 120 μm-thick under-fill material for measurement. The under-fill material for measurement was cut to a size of 10 mm (width)×30 mm (length) to provide a test piece, a tension test was conducted at a tension rate of 50 mm/min, a chuck-to-chuck distance of 10 mm and a temperature of 25° C. using “AUTOGRAPH ASG-50D Model” (manufactured by Shimadzu Corporation) as a tension tester. A ratio of a chuck-to-chuck distance, at the time when the test piece was ruptured, to the chuck-to-chuck distance before the test was determined, and defined as a rupture elongation (%).

(Measurement of Minimum Melt Viscosity)

The minimum melt viscosity of the under-fill material is a value measured by a parallel plate method using a rheometer (RS-1 manufactured by HAAKE Company). More specifically, the melt viscosity was measured over a range of from 40° C. to 200° C. under the conditions of a gap of 100 μm, a rotation plate diameter of 20 mm, a rotation speed of 5 s⁻¹ and a temperature rise rate of 10° C./minute, and the minimum values of the melt viscosity over a range of not lower than 40° C. and lower than 100° C. and a range of not lower than 100° C. and not higher than 200° C. were defined as minimum melt viscosities over the respective temperature ranges.

(Evaluation of Workability of Under-Fill Material and Peeling Property of Under-Fill Material from Base Material)

The sealing sheet was cut to a size of 7.5 mm (length)×7.5 mm (width), and the under-fill material and the BGA substrate were bonded to each other with the under-fill material side facing the BGA substrate. Bonding was performed at a linear pressure of 0.2 MPa using a roll laminator at 70° C. under a reduced pressure of 1,000 Pa. Thereafter, the base material was peeled off from the under-fill material to prepare a substrate with an under-fill material. Regarding workability of the under-fill material, a sample was rated “◯” when operations ranging from cutting of the under-fill material to bonding of the under-fill material were performed without problems, and a sample was rated “x” when deformation or rupture of the under-fill material, peeling off the under-fill material from the base material, or the like occurred. Regarding the peeling property from the base material, a sample was rated “◯)” when it was able to peel the base material without problems at the time of peeling off the base material from the under-fill material, and a sample was rated “x” when the under-fill material was transferred to the base material, or the under-fill material was peeled off from the base material.

(Evaluation on Generation of Voids During Mounting)

A 7.3 mm-square and 500 μm-thick semiconductor chip was heat pressure-bonded to the BGA substrate to perform mounting of the semiconductor chip with the bump-formed surface of the semiconductor chip and the BGA substrate facing each other under the heat pressure-bonding conditions described below. In this way, a semiconductor device with a semiconductor chip mounted on a BGA substrate was obtained.

<Heat Pressure-Bonding Conditions>

Pickup device: trade name “FCB-3” manufactured by Panasonic Corporation

Heating temperature: 260° C.

Load: 30 N

Retention time: 10 seconds

Evaluation on generation of voids was performed in the following manner: the semiconductor device prepared in the above-described procedure was cut and polished at the interface between the semiconductor chip and the under-fill material, the polished surface was observed using an image recognition device (trade name “C9597-11” manufactured by Hamamatsu Photonics K.K.; magnification: 1000), and the ratio of the total area of void portions to the area of the under-fill material was calculated. A sample was rated “◯” when the ratio of the total area of void portions to the area of the under-fill material in the observed image of the polished surface is 0 to 5%, and a sample was rated “x” when this ratio was more than 5%.

TABLE 1

| | | | | | | Comparative | Comparative | Comparative |
|---|---|---|---|---|---|---|---|---|
| | | Example 1 | Example 2 | Example 3 | Example 4 | Example 1 | Example 2 | Example 3 |
| | | Under-fill material | | | | | | |
| | | A | B | C | D | E | F | G |
| Composition | Epoxy resin 1 | 15 | 10 | 15 | 20 | 5 | 0 | 20 |
| | Epoxy resin 2 | 5 | 10 | 5 | 0 | 15 | 20 | 0 |
| | Phenol resin 1 | 23.4 | 23.4 | 11.7 | 10.4 | 23.4 | 23.4 | 11.7 |
| | Phenol resin 2 | 0 | 0 | 11.7 | 13 | 0 | 0 | 11.7 |
| | Elastomer 1 | 9.5 | 9.5 | 0 | 0 | 9.5 | 0 | 10.5 |
| | Elastomer 2 | 0 | 0 | 11.9 | 14.5 | 0 | 23.5 | 0 |
| | Filler | 67.5 | 67.5 | 58 | 45 | 67.5 | 67.5 | 20 |
| | Organic acid | 2.7 | 2.7 | 2.7 | 2.7 | 2.7 | 2.7 | 2.7 |
| | Curing agent | 0.15 | 0.15 | 0.15 | 0.15 | 0.15 | 0.15 | 0.15 |

| | | | | | | | |
|---|---|---|---|---|---|---|---|
| Rupture elongation [%] | 140 | 30 | 55 | 90 | 5 | 250 | 800 |
| Minimum melt viscosity | 6,500 | 5,900 | 8,000 | 12,000 | 6,200 | 80,000 | 3,900 |
| (not lower than 40° C. and | | | | | | | |
| lower than 100° C.) [Pa · s] | | | | | | | |
| Minimum melt viscosity | 380 | 400 | 1600 | 2300 | 350 | 5,000 | 20 |
| (not lower than 100° C. and | | | | | | | |
| not higher than 200° C.) [Pa · s] | | | | | | | |
| Peel strength from base material | 24 | 19 | 8 | 8 | 20 | 3 | 73 |
| [mN/20 mm] | | | | | | | |
| Workability | ∘ | ∘ | ∘ | ∘ | x | ∘ | x |
| Peeling property | ∘ | ∘ | ∘ | ∘ | ∘ | x | ∘ |
| Voids during mounting | ∘ | ∘ | ∘ | ∘ | ∘ | x | x |

For the under-fill materials of examples, workability of the under-fill material and the peeling property of the under-fill material from the base material were satisfactory, and voids during mounting were sufficiently suppressed. On the other hand, the under-fill material of Comparative Example 1 had an excessively small rupture elongation, so that rupture occurred during operations. The under-fill material of Comparative Example 2 had an excessively high minimum melt viscosity, so that the base material was peeled off during operations, and in addition, during mounting of the semiconductor chip, embeddability of the under-fill material in irregularities of the semiconductor chip was not sufficient, and thus voids were generated. Further, the under-fill material of Comparative Example 3 had an excessively low minimum melt viscosity, and hence high adherability, so that workability was deteriorated, and in addition, outgas components from the under-fill material caused generation of voids during mounting.

### REFERENCE CHARACTERS LIST

1 Base material
2 Under-fill material
3 Semiconductor wafer
4 Bump electrode
5 Semiconductor element
6 Adherend
7 Conducting material
10 Sealing sheet
20 Substrate with sealing sheet
30 Semiconductor device

1. A sealing sheet, comprising
a base material, and
an under-fill material having the following characteristics provided on the base material:
a 90° peel strength from the base material is not less than 1 mN/20 mm and not more than 50 mN/20 mm;
a rupture elongation at 25° C. is 10% or more;
a minimum viscosity at a temperature of not lower than 40° C. and lower than 100° C. is 20000 Pa·s or less; and
a minimum viscosity at a temperature of not lower than 100° C. and not higher than 200° C. is 100 Pa·s or more.

2. The sealing sheet according to claim 1, wherein the under-fill material contains a thermoplastic resin and a thermosetting resin.

3. The sealing sheet according to claim 2, wherein the thermosetting resin contains a thermosetting resin that is liquid at 25° C., and
a ratio of the weight of the thermosetting resin that is liquid at 25° C. to the total weight of the thermosetting resin is not less than 5% by weight and not more than 40% by weight.

4. The sealing sheet according to claim 2, wherein the thermoplastic resin contains an acrylic resin, and the thermosetting resin contains an epoxy resin and a phenol resin.

5. The sealing sheet according to claim 1, wherein the under-fill material contains a flux agent.

6. The sealing sheet according to claim 1, wherein the base material contains a thermoplastic resin.

7. The sealing sheet according to claim 6, wherein the thermoplastic resin is polyethylene terephthalate.

8. A method for producing a semiconductor device which comprises an adherend, a semiconductor element electrically connected to the adherend, and an under-fill material filling a space between the adherend and the semiconductor element, the method comprising the steps of:
providing the sealing sheet according to claim 1;
bonding the under-fill material of the sealing sheet to the adherend so as to cover a position of connection to the semiconductor element on the adherend;
peeling off the base material from the under-fill material bonded to the adherend; and
electrically connecting the semiconductor element and the adherend to each other through a bump electrode formed on the semiconductor element while filling the space between the adherend and the semiconductor element with the under-fill material.

9. A substrate with a sealing sheet, comprising
a substrate, and
the sealing seat according to claim 1, the sealing sheet being bonded to the substrate.
